(19) United States
(12) Patent Application Publication
(10) Pub. No.: US 2009/0072348 A1
(43) Pub. Date: Mar. 19, 2009

(54) Integrated Circuits; Methods for Manufacturing an Integrated Circuit and Memory Module

(76) Inventors: Ulrich Klostermann, Munich (DE); Gill Yong Lee, Dresden (DE)

Correspondence Address: SLATER & MATSIL, L.L.P., 17950 PRESTON ROAD, SUITE 1000, DALLAS, TX, 75252, US

(21) Appl. No.: 11/857,703

(22) Filed: Sep. 19, 2007

(51) Int. Cl. H01L 29/00; H01L 21/425

(52) U.S. Cl. 257/530; 438/533; 257/E29.001; 257/E21.473

(57) ABSTRACT

Embodiments of the present invention relate generally to integrated circuits, to methods for manufacturing an integrated circuit and to a memory module. In an embodiment of the invention, an integrated circuit is provided having a programmable arrangement. The programmable arrangement includes a substrate, at least one first electrode disposed in or above the substrate, ion conductor doping material disposed above the at least one first electrode, ion conductor material disposed above the ion conductor doping material, and at least one second electrode disposed above the ion conductor material.

### TECHNICAL FIELD

Embodiments of the present invention relate generally to integrated circuits, to methods for manufacturing an integrated circuit and to a memory module.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a cross sectional view of a programmable arrangement;

FIG. 2 shows a cross sectional view of a programmable arrangement in which an undesired formation of a dendrite between a first electrode and a second electrode is illustrated;

FIG. 3 shows a cross sectional view of a programmable arrangement in accordance with an embodiment of the invention;

FIGS. 4A to 4C show cross sectional views through a portion of the programmable arrangement of FIG. 3 at different time instants of a method for manufacturing of the programmable arrangement in accordance with a first embodiment of the invention;

FIGS. 5A to 5E show cross sectional views through a portion of the programmable arrangement of FIG. 3 at different time instants of a method for manufacturing of the programmable arrangement in accordance with a second embodiment of the invention;

FIGS. 6A and 6B show cross sectional views through a portion of the programmable arrangement of FIG. 3 at different time instants of a method for manufacturing of the programmable arrangement in accordance with a third embodiment of the invention; and

FIGS. 7A and 7B show a memory module (FIG. 7A) and a stackable memory module (FIG. 7B) in accordance with an embodiment of the invention.

### DETAILED DESCRIPTION OF ILLUSTRATIVE EMBODIMENTS

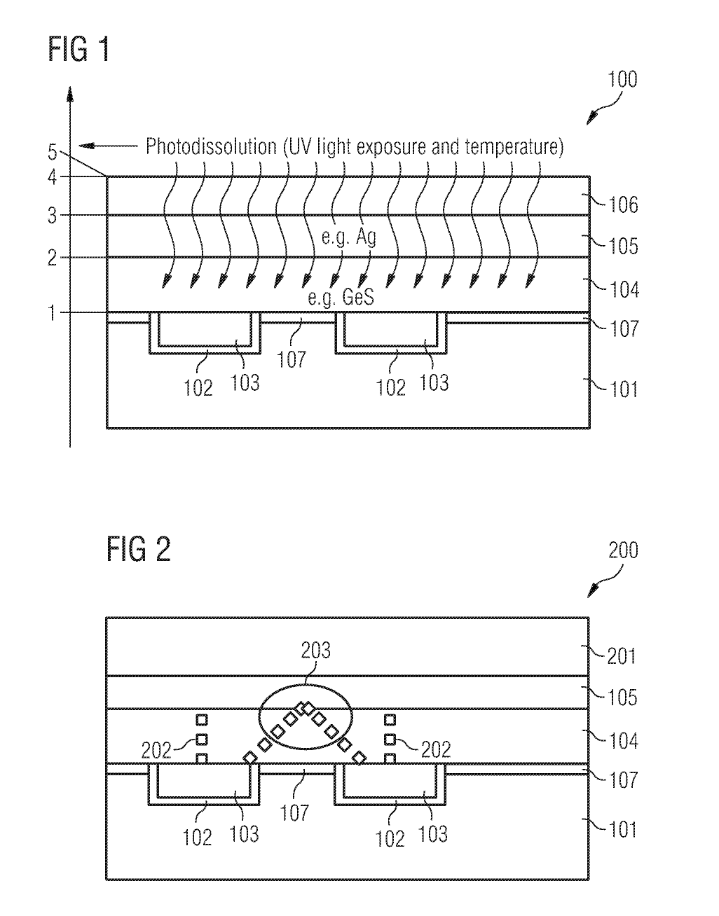

FIG. 1 shows a common programmable arrangement 100, in which a surface region of a dielectric 101 is patterned into a substrate 101 made of a dielectric according to a damascene method, so that trenches are formed. A diffusion barrier layer 102 is applied onto the upper surface of the substrate 101 and the side walls of the trench and the bottom of the trench. The diffusion barrier layer 102 is positioned on the sidewalls and the bottom of the first electrodes 103 to be formed. Laterally between the first electrodes 103 to be formed and electrically isolating the portions of the diffusion barrier layer 102, an isolating layer 107, e.g. made of silicon nitride, is provided on the upper surface of the substrate, which is free of the material of the diffusion barrier layer 102. A plurality of first electrodes 103 made of tungsten or nickel are located next to one another and applied onto the diffusion barrier layer 102 optionally including a barrier liner between the diffusion barrier layer 102 and the respective first electrode 103. An ion conducting layer is applied to the planarized surface of the first electrode 103 and the exposed diffusion barrier layer 102 in form of an isolating matrix 104, usually made of germanium-sulfide (GeS) or germanium-selenide (GeSe). The isolating matrix 104 is also referred to as a first functional layer 104. A second functional layer 105, usually made of silver, is applied to the first functional layer 104 and then, a cover layer 106 is applied to the second functional layer 105.

Silver is driven from the second functional layer 105 into the first functional layer 104 by means of photo dissolution, in other words using a radiation of ultraviolet light with a wavelength of approximately 500 nm, for example, or using a corresponding temperature treatment of the programmable arrangement 100. The silver being introduced into the first functional layer clearly forms electrically conductive regions within the electrically isolating matrix of germanium sulfide or germanium selenide. The cover layer 106 protects the functional layers 104 and 105 during the photo dissolution process.

Metal dendrites 202 are formed between an upper electrode 201, which is applied to the functional layers 104, 105 after the removing of the cover layer 106 (see programmable arrangement 200 in FIG. 2), and a respective first electrode 103 by applying a corresponding electrical voltage between the upper electrode 201 and a corresponding first electrode 103 due to a reduction/oxidation process, which occurs between the materials of the first functional layer 104 and the second functional layer 105 and possibly the upper electrode 201. The upper electrode 201 is usually made of a relatively easily oxidizable material, for example, silver.

When the dendrite 202 is formed between the upper electrode 201 and a respective first electrode 103 the electrical resistance of an electrical part between the respective first electrode 103 and the upper electrode 201, which will be referred to a second electrode 201 in the following, changes.

In order to position a maximal high number of first electrodes 103 in the programmable arrangement 200, for example, in a memory array, it is desirable, to reduce the lateral resolution, in other words the distance between the first electrodes 103, as far as possible.

With the decrease of the distance between the first electrodes 103, the risk of cross talk effect, clearly increases the risk, that, although it is desired to form a dendrite 202 between a first electrode 103 and the second electrode 201, a dendrite is formed between an adjacent other first electrode 103 and the second electrode 201. This may result in the formation of cross talk dendrites 203 at an electrode not to be programmed during the programming of another first electrode 103 due to electromagnetic edge effects and the overlapping electromagnetic fields that are affected thereby.

As will be described in more detail below, exemplary embodiments of the invention provide an easy mechanism to prevent a possible cross talk between adjacent first electrodes.

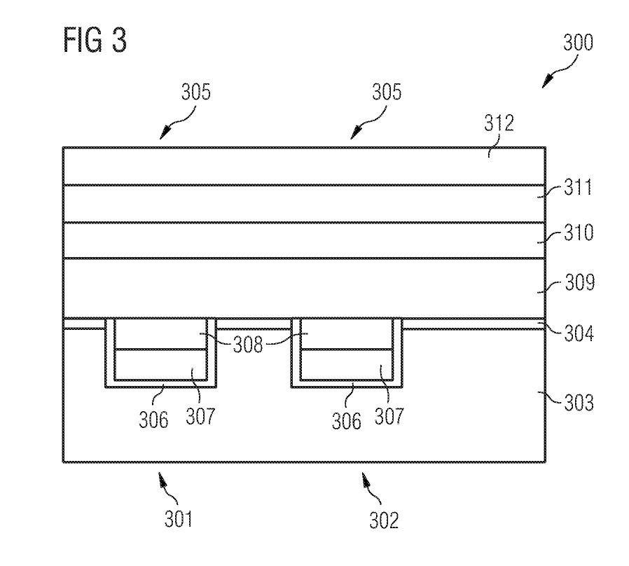

FIG. 3 shows a cross sectional view of an integrated circuit having a programmable arrangement 300. In an embodiment of the invention, the programmable arrangement 300 is configured as a memory cell arrangement 300.

In an embodiment of the invention, the memory cell arrangement 300 includes two memory cells 301 and 302, in general an arbitrary number of memory cells, which may be, e.g., arranged in rows and columns within a regular memory cell array. It should be mentioned that an arbitrary number of memory cells may be provided in a regular manner or in an irregular manner within the memory cell arrangement 300, e.g., thousands or millions of memory cells.

As shown in FIG. 3, each memory cell 301, 302 is formed such that a diffusion barrier layer 304 (e.g., made of silicon nitride, aluminum oxide, tantalum oxide, carbon) is applied on or above a dielectric (e.g., a dielectric substrate) 303, e.g., made of silicon oxide of silicon nitride or any other electrically isolating material.

Trenches or holes 305 are formed extending through the diffusion barrier layer 304 and into the dielectric 303. Liner layers 306, e.g., made of titanium (Ti), titanium nitride (TiN), tantalum (Ta) or tantalum nitride (TaN) are formed on the side walls and on the bottom of the trenches or holes 305, e.g., by means of deposition. Metal is applied on or above the liner layers 306 to form the first electrodes 307, wherein the metal is introduced into the trenches or holes 305. Tungsten, in an alternative embodiment of the invention, nickel, may be used as the metal. In an embodiment of the invention, the trenches or holes 305 are not completely filled with the metal for the first electrodes 307. In an embodiment of the invention, ion conductor doping material 308 is applied on or above the first electrodes 307 in a selective manner or over the entire surface, as will be discussed in more detail below. The trenches or holes 305 are completely filled and slightly overfilled with the ion conductor doping material 308, in accordance with an embodiment of the invention with silver, in an alternative embodiment of the invention with copper or tungsten or with a combination or alloy of two of the three mentioned materials or with a combination or alloy of all three mentioned materials, so that excessive ion conductor doping material 308 projecting out of the trenches or holes 305 remains. In an embodiment of the invention, the excessive ion conductor doping material 308 is removed, e.g., by means of a chemical mechanical polishing (CMP) process.

The metal projecting out of the trenches or holes 305 and thus the excessive metal is removed, e.g., by means of a chemical mechanical polishing (CMP) process such that two first electrodes are formed, which are electrically isolated from each other, e.g., by means of the inter-metal dielectric, in an embodiment of the invention, by means of the substrate 303.

Ion conductor material 309, e.g., a chalcogenide, is applied on or above the planarized surface of the first electrodes and the exposed upper surface regions of the diffusion barrier layer 304.

Ion conductor material 309 can be any suitable solid state electrolyte, a metal ion containing glass, a metal ion containing amorphous semiconductor, a chalcogenide glass, which optionally contains metal ions or the like, can be provided. In general, the chalcogenide material contains, for example, as described above, a compound, which contains sulfur, selenium and/or tellurium, for example, also in ternary, quaternary or higher level compounds.

In an embodiment of the invention, the ion conductor material 309 includes a material being selected from a group of materials consisting of:

CdSe or ZnCdS (in these embodiments, e.g., silver may be used for the metal),

CuO₂, TiO₂, NiO, CoO, Ta₂O₅ (in these embodiments, e.g., titanium or nickel may be used for the metal),

WO₂, Al:ZnOx, Al₂O₃ (in these embodiments, e.g., aluminum may be used for the metal),

Cu:MoOₓ, SrTiOₓ, Nb₂O₅₋ₓ, Pr₁₋ₓCaₓMnO₃, Cr:SrZrO₃, Nb:SrTiO₃ (in these embodiments, e.g., copper may be used for the metal),

As an example, the ion conductor material 309 is made of a chalcogenide glass, which contains a metal ion compound, wherein the metal is selected from different metals of group I or group II of the periodic system, for example, silver copper, zinc or a combination thereof.

The ion conductor material 309 has, according to this exemplary embodiment of the invention, a layer thickness in the range from about 5 nm to about 300 nm, for example in the range from about 10 nm to about 40 nm, for example about 20 nm.

A second functional layer, in accordance with this exemplary embodiment of the invention made of silver, is applied in two dimensions to fully recover the ion conductor material 309, which is also referred to as first functional layer. In an embodiment of the invention, the ion conductor doping material is arranged between the substrate 303 and the ion conductor material 309 and not in the conventional manner, on the side of the ion conductor material 309 which is opposite to the substrate.

The second functional layer, in other words, the ion conductor doping material 308, may have a layer thickness in the range from approximately 5 nm to approximately 50 nm, for example, a layer thickness in the range from approximately 10 nm to approximately 30 nm, for example, a layer thickness of approximately 20 nm.

In a subsequent diffusion step, which is not shown in the figures, ultraviolet light having a wavelength of less than approximately 500 nm is radiated onto the arrangement that is shown in a cross sectional view, thereby effecting a diffusion of a portion of the silver of the second functional layer 308 into the ion conductor material 309, clearly an insulating matrix, thereby forming electrically conductive regions within the ion conductor material 309, where electrically conductive regions are electrically isolated from one another by means of the isolating matrix made of the ion conductor material. As an alternative or in addition, a portion of the silver of the second functional layer 308 can be driven into the ion conductor material 309 by means of a corresponding annealing step by heating the arrangement 300.

At least one cover layer, is applied on or above the ion conductor material 309, in an embodiment of the invention, a first cover layer 310 made of, e.g., ruthenium (Ru) and a second cover layer 311 made of, e.g., titanium or titanium nitride being applied on or above the first cover layer 310. In an embodiment of the invention, a second electrode 312 covering the whole surface, is applied on or above the second cover layer 311. The second electrode 312 may be made of, e.g., copper, tungsten, zinc or another suitable metal or another suitable electrically conductive material.

The first cover layer 310 and the second cover layer 311 electrically couple the second electrode 312 with the ion conductor material 309 and clearly form a partial system of a plurality of functional layers in order to set or achieve additional characteristics such as, e.g., thermal stability, a low diffusion of material between the layers, an improved planarity of the layer surfaces and an improved growing of individual layers of the layer stack of the memory cell arrangement 300.

In an embodiment of the invention, the first cover layer 310 and the second cover layer 311 may be made of, e.g., tantalum, tantalum nitride, titanium, titanium nitride, aluminum, ruthenium or another suitable metal or another suitable material which is electrically conductive, depending on the desired characteristics of the cover layer combination.

In an alternative embodiment of the invention, the second electrode 312 may include a material combination of a plurality of layers, e.g., a layer combination including a titanium layer, an aluminum layer arranged on or above the titanium layer, and a titanium layer arranged on or above the aluminum layer.

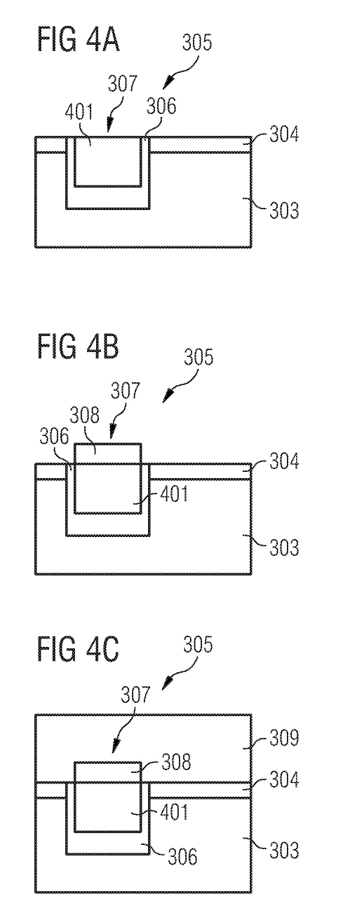

FIGS. 4A to 4C show a portion of the programmable arrangement, e.g., the memory cell arrangement, to be manufactured at different time instants during its manufacture.

As shown in FIG. 4A, a substrate 303 made of a dielectric material 303 is applied on or above a silicon substrate (not shown in the figures), in which electronic circuits may be monolithically integrated, e.g., transistors, amplifier circuits, and the like. In an embodiment of the invention, one or more select transistors (not shown in the figures) are provided below a respective memory cell, which may be accommodated in a respective trench or hole 305, as will be described in more detail below, to individually select the respective memory cell.

A diffusion barrier layer 304 made, e.g., of silicon nitride or silicon oxide having a layer thickness in the range from about 50 nm to about 100 nm is deposited on or above the dielectric 303 made, e.g., of silicon oxide or silicon nitride, e.g., by means of a chemical vapor deposition (CVD) process. A respective trench or hole 305, in which a first electrode of a respective memory cell to be formed should be introduced, is formed into the diffusion barrier layer 304 which is deposited over the entire surface, e.g., by means of lithography and etching.

In an embodiment of the invention, the trench or hole 305 extends respectively completely through the diffusion barrier layer 304 and the dielectric layer 303 and projects into the silicon substrate 303.

In general, the diffusion barrier layer 304 may be configured such that it serves as a diffusion barrier with regard to the respective electrically conductive material, which is introduced into the ion conductor material 309, e.g. with regard to silver. Furthermore, the diffusion barrier layer 304 optionally additionally serves as a stop layer for a chemical mechanical polishing (CMP) process, which will be described in more detail below.

In an embodiment of the invention, an optional liner layer is (e.g., conformally) deposited in the trench or hole 305 and on or above the upper surface of the diffusion barrier layer 304, i.e., on the sidewalls of the trench or hole 305 and the bottom of the trench or hole 305. In an embodiment of the invention, titanium (Ti), titanium nitride (TiN), tantalum (Ta) or tantalum nitride (TaN) may be provided as the material for the liner layer 306.

In an embodiment of the invention, the liner layer 306 acts as a diffusion barrier in the case where, e.g., copper is used as the material for the first electrode, as will be described in more detail below.

In an embodiment of the invention, metal 401 is deposited (also over the entire surface) on or above the conformally deposited (over the entire surface) liner layer 306, wherein the liner layer 306 may have a layer thickness in the range of a few nm. In an embodiment of the invention, copper may be used as the metal, in an alternative embodiment of the invention, tungsten, zinc, tantalum, tantalum nitride, or tungsten nitride may be used as the metal. In an embodiment of the invention, a respective first electrode 307 should be subsequently formed from the deposited metal.

After having deposited the metal layer 401, the metal layer 401 and the liner layer 306 are removed by means of a chemical mechanical polishing (CMP) process with stop of the process on the upper surface of the diffusion barrier layer 304. Thus, the respective electrically conductive material in a respective trench is electrically isolated from the electrically conductive material of an adjacent trench or hole 305, thereby forming respective first electrodes 307.

In an embodiment of the invention, as shown in FIG. 4B, silver material is deposited in a selective manner on or above the exposed upper surfaces of the first electrodes 307, in general, the ion conductor doping material 308 being used for doping the ion conductor layer 309. In an embodiment of the invention, in difference to the embodiment shown in FIG. 3, the ion conductor doping material 308 is not deposited into the trench or hole 305, but it is deposited on or above the respective upper surface of the first electrode above the trench or hole 305. In an embodiment of the invention, the ion conductor doping material 308 may be deposited having a layer thickness in the range from about 5 nm to about 50 nm, e.g., having a layer thickness in the range from about 10 nm to about 30 nm.

Then, as shown in FIG. 4C, isolating material 309 is deposited on or above the structure shown in FIG. 4B, in an embodiment of the invention made, e.g., of germanium selenide of germanium sulfide. Then, the two cover layers 310, 311 and the second electrode 312 are deposited on or above the structure shown in FIG. 4C, thereby completing the memory cell arrangement.

The isolating material 309, which may serve as the ion conductor layer 309, may be manufactured having a layer thickness in the range from about 5 nm to about 50 nm, e.g. having a layer thickness in the range from about 10 nm to about 30 nm, in an embodiment of the invention, having a layer thickness in the range similar to the layer thickness of the ion conductor doping material layer 308.

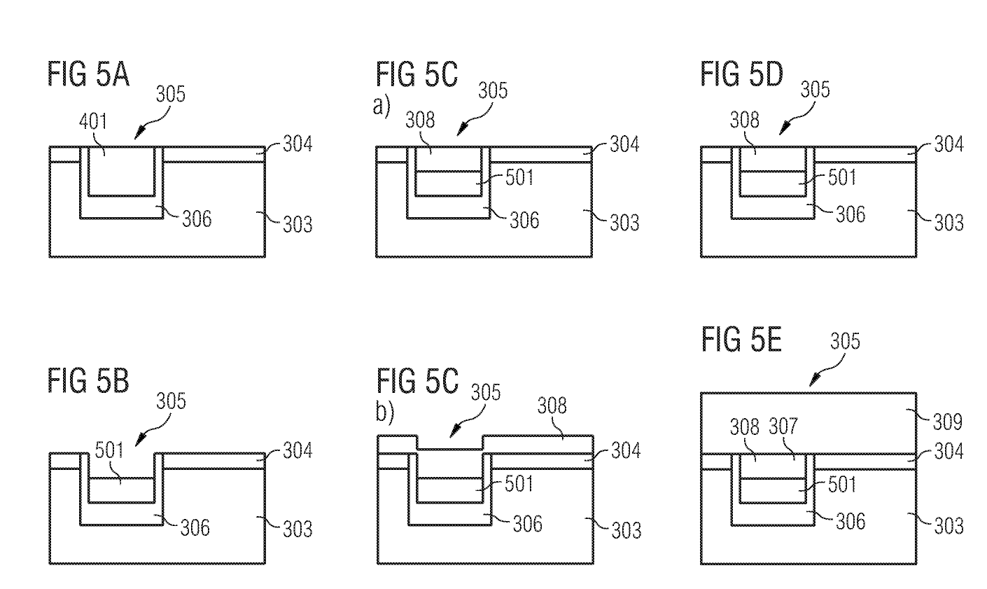

FIGS. 5A to 5E show cross sectional views through a portion of the programmable arrangement of FIG. 3 at different time instants of a method for manufacturing of the programmable arrangement in accordance with a second embodiment of the invention.

FIG. 5A substantially corresponds to the structure shown in FIG. 4A. Therefore, a repeated description of the structure and of the manufacturing thereof is omitted for reasons of brevity.

In difference to the embodiment illustrated in the FIGS. 4A to 4C, as shown in FIG. 5B, the metal of the first electrodes 307, which extends to the upper edge of the trench or hole 305 after the chemical mechanical polishing process, will now be etched back or recessed by a predetermined height, e.g., by approximately 30% to approximately 50% of the trench depth, e.g., by means of wet chemical etching or by means of dry chemical etching, thereby forming a recessed metal 501.

In a subsequent process, in which the ion conductor doping material 308 is introduced into the trench or hole 305, in other words, into the region, in which the metal of the first electrodes 307 have been etched back, two different variants with regard to the deposition process to be used are provided and are shown in two different figures, namely in FIG. 5Ca and FIG. 5Cb.

In an embodiment of the invention, the ion conductor doping material 308, e.g., silver, copper, tungsten, titanium, nickel, aluminum or a combination of these materials, is selectively introduced into the trench 305 by means of an electroless deposition process (see FIG. 5Ca) (in an alternative embodiment of the invention by means of a electrodeposition process) and the excessive material will then be removed, e.g., by means of a CMP process with stop on the upper surface of the diffusion barrier layer 304. In an alternative embodiment of the invention, the ion conductor doping material 308, in an embodiment of the invention, e.g., silver, may be deposited over the whole surface and inter alia may be introduced into the trenches or holes 305, e.g. by means of a sputter deposition process, in general, e.g., by means of a physical vapor deposition (PVD) process, thereby completely filling the trenches or holes 305 (see FIG. 5Cb)

As shown in FIG. 5D, the excessive ion conductor doping material 308 projecting over the trenches or holes 305 is removed, e.g. planarized, e.g., by means of a CMP process, which is optional, e.g., in the variant in which the ion conductor doping material 308 is deposited using an electroless deposition process, wherein the CMP process may be stopped when the upper surface of the diffusion barrier layer 304 is reached or exposed.

Then, in an embodiment of the invention, the ion conductor layer 309 is deposited. Furthermore, subsequently, the cover layers 310, 311 and the second electrode 312 are deposited, thereby completing the memory cell arrangement 300. The layer thicknesses in the second embodiment of the invention are similar to the layer thicknesses as described in the context with the first embodiment of the invention as illustrated in the FIGS. 4A to 4C.

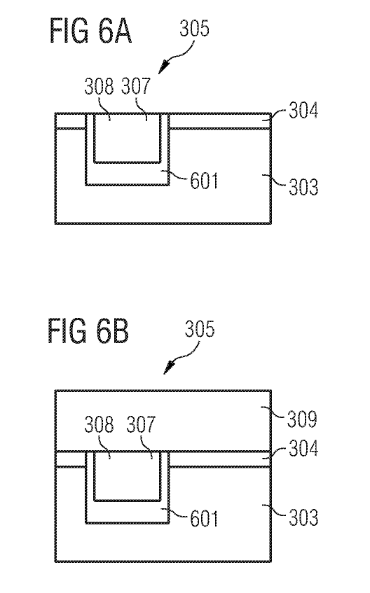

As shown in the FIGS. 6A and 6B, in an embodiment of the invention, silver is provided as the material for the liner layer 601 as well as for the respective first electrode 307. Thus, the first electrode 307 and the liner layer 601 are made of the same material, namely, e.g., made of silver. In this embodiment of the invention, the usage of a specific other material for the first electrode 307 may be dispensed with, since clearly the entire first electrode 307 may be used as a dopant supplier for the ion conductor layer 309 to be deposited.

The method for manufacturing the memory cell arrangement in accordance with this embodiment of the invention is substantially similar to the manufacturing method described above with the difference, that the trenches or holes 305 are not filled by means of a two-stage process, but rather that the trenches or holes 305 are filled and overfilled with the ion conductor doping material, which simultaneously serves as the material for the first electrode, that the excessive material is removed, e.g., by means of a CMP process with stop on the upper surface of the diffusion barrier layer 304 and that subsequently, the ion conductor layer 309 is deposited on or above the upper surface of the diffusion barrier layer 304 and the exposed upper surfaces of the silver electrodes 307, in general of the first electrodes 307, which are made of the ion conductor doping material.

The processing steps for completing the memory cell arrangement of this embodiment of the invention are similar to the processing steps for completing the memory cell arrangement in accordance with the above described embodiments shown in the FIGS. 4A to 4C and FIGS. 5A to 5E.

In the described embodiments of the invention, one effect seen may be due to the laterally limited and localized deposition of the ion conductor doping material in the context of the driving in of the doping material into the ion conductor layer 309, electrically conductive paths may be formed which are arranged locally above the respective first electrode. Almost no electrically conductive clusters can be formed between the respective first electrodes during the diffusion, so that there the probability is high, that electrically conductive paths may be formed upon application of a correspondingly sufficient electrical potential difference between the first electrode and the second electrode, which exceeds the threshold voltage of the memory cell, that the dendrites are formed in a concentrated localized manner, thereby preventing an undesired crosstalk, in other words, an undesired formation of dendrites between the second electrode and a non-selected first electrode.

Thus, clearly, an aspect of an embodiment of the invention may be seen in that the ion conductor doping material is deposited on or above the lower electrode of the solid state electrolyte memory cell and that the ion conductor doping material 308 is patterned such that the distribution of the doping ions after the driving in of the doping ions into the ion conductor layer 309 is also laterally and locally limited.

After the deposition of the second electrode 312, the ion conductor doping material 308 may be partially driven into the ion conductor layer 309, e.g., by means of irradiating the memory cell arrangement 300 with ultra violet (UV) light, which may have a wavelength of approximately 500 nm. In an alternative embodiment of the invention, the ion conductor doping material 308 may be partially driven into the ion conductor layer 309, e.g., by means of a temperature treatment, e.g., by means of annealing, in other words, by means of heating the memory cell arrangement 300.

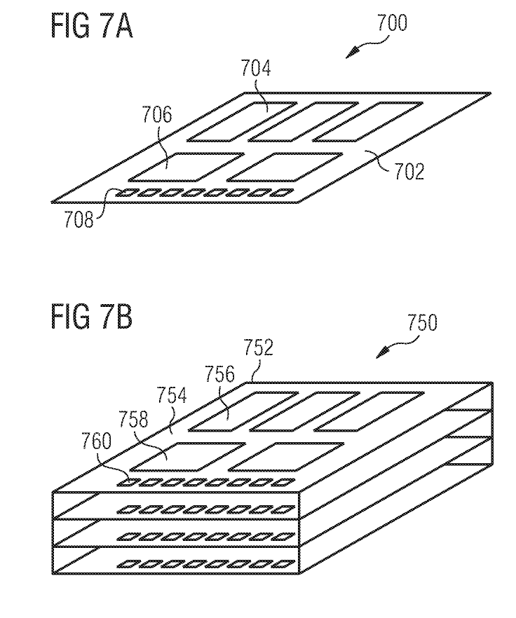

As shown in FIGS. 7A and 7B, in some embodiments, memory devices such as those described herein may be used in modules.

In FIG. 7A, a memory module 700 is shown, on which one or more memory devices 704 are arranged on a substrate 702. The memory device 704 may include numerous memory cells, each of which uses a memory element in accordance with an embodiment of the invention. The memory module 700 may also include one or more electronic devices 706, which may include memory, processing circuitry, control circuitry, addressing circuitry, bus interconnection circuitry, or other circuitry or electronic devices that may be combined on a module with a memory device, such as the memory device 704. Additionally, the memory module 700 includes multiple electrical connections 708, which may be used to connect the memory module 700 to other electronic components, including other modules.

As shown in FIG. 7B, in some embodiments, these modules may be stackable, to form a stack 750. For example, a stackable memory module 752 may contain one or more memory devices 756, arranged on a stackable substrate 754. The memory device 756 contains memory cells that employ memory elements in accordance with an embodiment of the invention. The stackable memory module 752 may also include one or more electronic devices 758, which may include memory, processing circuitry, control circuitry, addressing circuitry, bus interconnection circuitry, or other circuitry or electronic devices that may be combined on a module with a memory device, such as the memory device 756. Electrical connections 760 are used to connect the stackable memory module 752 with other modules in the stack 750, or with other electronic devices. Other modules in the stack 750 may include additional stackable memory modules, similar to the stackable memory module 752 described above, or other types of stackable modules, such as stackable processing modules, control modules, communication modules, or other modules containing electronic components.

In an embodiment of the invention, an integrated circuit is provided having a programmable arrangement. The programmable arrangement may include a substrate, at least one first electrode disposed in or above the substrate, ion conductor doping material disposed above the at least one first electrode, ion conductor material disposed above the ion conductor doping material, and at least one second electrode disposed above the ion conductor material.

In an embodiment of the invention, the ion conductor doping material is electrically coupled with the at least one first electrode.

In an embodiment of the invention, the ion conductor doping material is a material selected from a group of materials consisting of silver, copper, tungsten or a combination of these materials.

Furthermore, at least one diffusion barrier layer may be provided between the substrate and the at least one first electrode.

In an embodiment of the invention, the at least one first electrode is arranged in a trench being formed in the substrate.

In another embodiment of the invention, at least one intermediate layer may be provided between the main processing surface of the substrate and the ion conductor material wherein the at least one intermediate layer may be an etch stop layer and/or a diffusion barrier layer.

In an embodiment of the invention, the ion conductor doping material is selectively deposited on the upper surface of the at least one first electrode.

Furthermore, the at least one first electrode may have a height being smaller than the trench in which the first electrode is formed. Moreover, the trench region above the at least one first electrode may be at least partially filled with ion conductor doping material.

In another embodiment of the invention, the ion conductor material is made of chalcogenide material, wherein the ion conductor material may be made of chalcogenide material containing metal ions. The chalcogenide material may be selected from a group of materials consisting of sulfur, selenium, germanium, tellurium or a combination of these materials. The metal ions may be made of a metal being selected from of group of metals consisting of silver, copper, zinc or a combination of these materials.

In an embodiment of the invention, the at least one first electrode or the at least one second electrode is made of a material containing silver, copper or tungsten.

In an embodiment of the invention, the programmable arrangement of the integrated circuit further includes at least one metallic dendrite extending from the at least one second electrode into the ion conductor material in the direction to the at least one first electrode or at least one metallic dendrite extending from the at least one first electrode into the ion conductor material in the direction to the at least one second electrode.

In an embodiment of the invention, the programmable arrangement of the integrated circuit further includes at least one first cover layer disposed above the ion conductor material, wherein the at least one first cover layer may be made of a material being selected from a group of materials consisting of tantalum, tantalum nitride, titanium, titanium nitride, aluminum, ruthenium.

In an embodiment of the invention, the programmable arrangement of the integrated circuit further may include a dielectric layer disposed above the at least one second electrode.

In an embodiment of the invention, an integrated circuit having a programmable arrangement is provided. The programmable arrangement may include a substrate, at least one first electrode disposed in or above the substrate, ion conductor doping material disposed above the at least one first electrode, ion conductor material disposed above the ion conductor doping material, and at least one second electrode disposed above the ion conductor material.

The ion conductor doping material may be electrically coupled with the at least one first electrode.

The ion conductor doping material may be a material selected from a group of materials consisting of silver, copper, tungsten, titanium, nickel, aluminum or a combination of these materials.

In an embodiment of the invention, the integrated circuit may further include at least one diffusion barrier layer between the substrate and the at least one first electrode.

Furthermore, the at least one first electrode may be arranged in a trench being formed in the substrate.

In an embodiment of the invention, the integrated circuit may further include at least one intermediate layer between the main processing surface of the substrate and the ion conductor material.

The at least one intermediate layer may be an etch stop layer.

The at least one intermediate layer may be a diffusion barrier layer.

The ion conductor doping material may be selectively deposited on the upper surface of the at least one first electrode.

In an embodiment of the invention, the at least one first electrode has a height being smaller than the trench in which the first electrode is formed.

In an embodiment of the invention, the trench region above the at least one first electrode is at least partially filled with ion conductor doping material.

In an embodiment of the invention, the ion conductor material is made of chalcogenide material or of a material being selected from a group of materials consisting of: CdSe, ZnCdS, CuO₂, TiO₂, NiO, CoO, Ta₂O₅, WO₂, Al:ZnOₓ, Al₂O₃, Cu:MoOₓ, SrTiOₓ, Nb₂O₅₋ₓ, Pr₁₋ₓCaₓMnO₃, Cr:SrZrO₃, Nb:SrTiO₃.

Furthermore, the ion conductor material may be made of chalcogenide material containing metal ions.

The chalcogenide material may be selected from a group of materials consisting of sulfur, selenium, germanium, tellurium or a combination of these materials.

The metal ions may be made of a metal being selected from of group of metals consisting of silver, copper, zinc or a combination of these materials.

In an embodiment of the invention, the at least one first electrode or the at least one second electrode is made of a material containing silver, copper or tungsten.

In an embodiment of the invention, the integrated circuit may further include at least one metallic dendrite extending from the at least one second electrode into the ion conductor material in the direction to the at least one first electrode.

In an embodiment of the invention, the integrated circuit may further include at least one metallic dendrite extending from the at least one first electrode into the ion conductor material in the direction to the at least one second electrode.

In an embodiment of the invention, the integrated circuit may further include at least one first cover layer disposed above the ion conductor material.

The at least one first cover layer may be made of a material being selected from a group of materials consisting of tantalum, tantalum nitride, titanium, titanium nitride, aluminum, ruthenium.

In an embodiment of the invention, the integrated circuit may further include a dielectric layer disposed above the at least one second electrode.

In another embodiment of the invention, an integrated circuit having a programmable arrangement is provided. The programmable arrangement may include a substrate, at least one first electrode disposed in or above the substrate, an ion conductor doping material layer disposed above the at least one first electrode, an ion conductor material matrix being made of chalcogenide material disposed above the ion conductor doping material, and at least one second electrode disposed above the ion conductor material matrix.

The ion conductor doping material may be electrically coupled with the at least one first electrode.

The ion conductor doping material layer may be made of a material selected from a group of materials consisting of silver, copper, tungsten, titanium, nickel, aluminum or a combination of these materials.

Furthermore, in an embodiment of the invention, the integrated circuit may further include at least one diffusion barrier layer between the substrate and the at least one first electrode.

The at least one first electrode may be arranged in a trench being formed in the substrate.

In an embodiment of the invention, the integrated circuit may further include at least one intermediate layer between the main processing surface of the substrate and the ion conductor material.

The at least one intermediate layer may be an etch stop layer.

The at least one intermediate layer may be a diffusion barrier layer.

In an embodiment of the invention, the trench region above the at least one first electrode may be at least partially filled with ion conductor doping material.

The ion conductor material may be made of chalcogenide material or of a material being selected from a group of materials consisting of: CdSe, ZnCdS, CuO₂, TiO₂, NiO, CoO, Ta₂O₅, WO₂, Al:ZnOₓ, Al₂O₃, Cu:MoOₓ, SrTiOₓ, Nb₂O₅₋ₓ, Pr₁₋ₓCaₓMnO₃, Cr:SrZrO₃, Nb:SrTiO₃.

The ion conductor material layer may be made of chalcogenide material containing metal ions.

The chalcogenide material may be selected from a group of materials consisting of sulfur, selenium, germanium, tellurium or a combination of these materials.

In an embodiment of the invention, the metal ions are made of a metal being selected from of group of metals consisting of silver, copper, zinc or a combination of these materials.

The at least one first electrode or the at least one second electrode may be made of a material containing silver, copper or tungsten.

In an embodiment of the invention, the integrated circuit may further include at least one metallic dendrite extending from the at least one second electrode into the ion conductor material in the direction to the at least one first electrode.

In an embodiment of the invention, the integrated circuit may further include at least one metallic dendrite extending from the at least one first electrode into the ion conductor material in the direction to the at least one second electrode.

In an embodiment of the invention, a method for manufacturing an integrated circuit having a programmable arrangement is provided. The method may include depositing ion conductor doping material on or above at least one first electrode being disposed in or above a substrate, depositing ion conductor material on or above the ion conductor doping material, and forming at least one second electrode on or above the ion conductor material.

In an embodiment of the invention, the method may further include forming the at least one first electrode in, on or above the substrate.

In an embodiment of the invention, the method may further include forming a trench in the substrate, and forming the at least one first electrode in the trench.

The forming of the at least one first electrode may include forming the at least one first electrode in accordance with a damascene process.

Furthermore, depositing the ion conductor material on or above the ion conductor doping material may include a selective depositing of the ion conductor material on or above the ion conductor doping material.

Depositing the ion conductor material on or above the ion conductor doping material may include physically depositing the ion conductor material on or above the ion conductor doping material.

In another embodiment of the invention, a method for manufacturing an integrated circuit having a programmable arrangement is provided. The method includes depositing ion conductor doping material on or above at least one first electrode being disposed in or above a substrate, depositing ion conductor material on or above the ion conductor doping material, forming at least one second electrode on or above the ion conductor material, and driving at least some of the depositing ion conductor doping material into the depositing ion conductor material.

Driving at least some of the depositing ion conductor doping material into the depositing ion conductor material may include illuminating at least a portion of the programmable arrangement with light.

In an embodiment of the invention, driving at least some of the depositing ion conductor doping material into the depositing ion conductor material may include illuminating at least a portion of the programmable arrangement with ultraviolet light.

In an embodiment of the invention, driving at least some of the depositing ion conductor doping material into the depositing ion conductor material may include heating at least a portion of the programmable arrangement.

In yet another embodiment of the invention, an integrated circuit having a programmable arrangement is provided. The programmable arrangement may include a substrate, at least one first electrode means disposed in or above the substrate, ion conductor doping means disposed above the at least one first electrode means, ion conductor means disposed above the ion conductor doping means, and at least one second electrode means disposed above the ion conductor means.

In yet another embodiment of the invention, a memory module is provided. The memory module may include a plurality of integrated circuits, wherein at least one integrated circuit of the plurality of integrated circuits may include a programmable arrangement. The programmable arrangement may include a substrate, at least one first electrode disposed in or above the substrate, ion conductor doping material disposed above the at least one first electrode, ion conductor material disposed above the ion conductor doping material, and at least one second electrode disposed above the ion conductor material.

In an embodiment of the invention, the memory module is a stackable memory module in which at least some of the integrated circuits are stacked one above the other.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An integrated circuit having a programmable arrangement, the programmable arrangement comprising:
a substrate;
at least one first electrode disposed in or above the substrate;
ion conductor doping material disposed above the at least one first electrode;
ion conductor material disposed above the ion conductor doping material; and
at least one second electrode disposed above the ion conductor material.

2. The integrated circuit of claim 1, wherein the ion conductor doping material is electrically coupled with the at least one first electrode.

3. The integrated circuit of claim 1, wherein the ion conductor doping material is a material selected from a group of materials consisting of silver, copper, tungsten, titanium, nickel, aluminum or a combination of these materials.

4. The integrated circuit of claim 1, further comprising at least one diffusion barrier layer between the substrate and the at least one first electrode.

5. The integrated circuit of claim 1, wherein the at least one first electrode is arranged in a trench being formed in the substrate.

6. The integrated circuit of claim 1, further comprising at least one intermediate layer between a main processing surface of the substrate and the ion conductor material.

7. The integrated circuit of claim 6, wherein the at least one intermediate layer is an etch stop layer.

8. The integrated circuit of claim 6, wherein the at least one intermediate layer is a diffusion barrier layer.

9. The integrated circuit of claim 1, wherein the ion conductor doping material is selectively deposited on an upper surface of the at least one first electrode.

10. The integrated circuit of claim 5, wherein the at least one first electrode has a height being smaller than the trench in which the first electrode is formed.

11. The integrated circuit of claim 9, wherein a trench region above the at least one first electrode is at least partially filled with ion conductor doping material.

12. The integrated circuit of claim 1, wherein the ion conductor material is made of chalcogenide material or of a material being selected from a group of materials consisting of: CdSe, ZnCdS, CuO₂, TiO₂, NiO, CoO, Ta₂O₅, WO₂, Al:ZnOₓ, Al₂O₃, Cu:MoOₓ, SrTiOₓ, Nb₂O₅₋ₓ, Pr₁₋ₓCaₓMnO₃, Cr:SrZrO₃, Nb:SrTiO₃.

13. The integrated circuit of claim 12, wherein the ion conductor material is made of chalcogenide material containing metal ions.

14. An integrated circuit having a programmable arrangement, the programmable arrangement comprising:
a substrate;
at least one first electrode disposed in or above the substrate;
an ion conductor doping material layer disposed above the at least one first electrode;
an ion conductor material matrix being made of chalcogenide material disposed above the ion conductor doping material layer; and
at least one second electrode disposed above the ion conductor material matrix.

15. A method for manufacturing an integrated circuit having a programmable arrangement, the method comprising:
depositing ion conductor doping material on or above at least one first electrode being disposed in or above a substrate;
depositing ion conductor material on or above the ion conductor doping material; and
forming at least one second electrode on or above the ion conductor material.

16. The method of claim 15, further comprising forming the at least one first electrode in, on or above the substrate.

17. The method of claim 15, further comprising:
forming a trench in the substrate; and
forming the at least one first electrode in the trench.

18. The method of claim 15, wherein the forming the at least one first electrode comprises forming the at least one first electrode in accordance with a damascene process.

19. The method of claim 15, wherein the depositing ion conductor material on or above the ion conductor doping material comprises a selective depositing of the ion conductor material on or above the ion conductor doping material.

20. The method of claim 15, wherein the depositing ion conductor material on or above the ion conductor doping material comprises physically depositing the ion conductor material on or above the ion conductor doping material.

21. A method for manufacturing an integrated circuit having a programmable arrangement, the method comprising:
depositing ion conductor doping material on or above at least one first electrode being disposed in or above a substrate;
depositing ion conductor material on or above the ion conductor doping material;
forming at least one second electrode on or above the ion conductor material; and
driving at least some of the ion conductor doping material into the ion conductor material.

22. The method of claim 21, wherein the driving at least some of the ion conductor doping material into the ion conductor material comprises illuminating at least a portion of the programmable arrangement with light.

23. The method of claim 22, wherein the driving at least some of the ion conductor doping material into the ion conductor material comprises illuminating at least a portion of the programmable arrangement with ultraviolet light.

24. The method of claim 21, wherein the driving at least some of the ion conductor doping material into the ion conductor material comprises heating at least a portion of the programmable arrangement.

25. A memory module, comprising:
a plurality of integrated circuits, wherein at least one integrated circuit of the plurality of integrated circuits comprises a programmable arrangement, the programmable arrangement comprising:
a substrate;
at least one first electrode disposed in or above the substrate, ion conductor doping material disposed above the at least one first electrode;
ion conductor material disposed above the ion conductor doping material; and
at least one second electrode disposed above the ion conductor material.
